(19) United States
(12) Patent Application Publication
(10) Pub. No.: US 2026/0305280 A1
(43) Pub. Date: Oct. 1, 2026

(54) METHOD OF FORMING ELECTRICALLY CONDUCTIVE LINES WITH CONTROLLED COEFFICIENT OF THERMAL EXPANSION

(71) Applicant: INPACK TECHNOLOGIES - LIMITED PARTNERSHIP, Migdal HaEmek (IL)

(72) Inventor: Joseph KAPLUN, Petah Tikva (IL)

(21) Appl. No.: 19/479,691

(22) PCT Filed: Apr. 18, 2024
(86) PCT No.: PCT/IL2024/050385

§ 371 Date: Oct. 28, 2025

Related U.S. Application Data
(60) Provisional application No. 63/463,352, filed on May 2, 2023.

(51) Int. Cl. H10W 20/00; C23C 24/10; H10P 14/46

(52) U.S. Cl. CPC H10W 20/031; C23C 24/106; H10P 14/46

(57) ABSTRACT

Disclosed herein is a method for forming electrically conductive lines with a controlled thermal expansion coefficient (CTE), the method comprising: applying a suspension on a surface of a substrate, the suspension comprising a solvent and a solid component, the solid component comprising a mixture of at least two types of electrically conductive nanoparticles, sintering the suspension to form the electrically conductive lines, and removing a non-sintered portion of the suspension, wherein the at least two types of electrically conductive nanoparticles comprise: a first type of electrically conductive nanoparticles having a positive CTE and a second type of electrically conductive nanoparticles having a different CTE than the first type of conductive nanoparticles, and wherein a ratio between the at least two types of electrically conductive nanoparticles determines a final CTE of the electrically conductive lines.

### TECHNICAL FIELD

The present disclosure relates generally to semiconductor devices, and more particularly, to methods for forming electrically conductive lines with controlled coefficient of thermal expansion.

### BACKGROUND

The continuous growth and development of the semiconductor industry aims to minimize the size of electronic devices while increasing the performance and yield thereof, by manufacturing highly integrated systems. For example, by designing a plurality of integrated circuit chips in a single module. Typically, the integrated circuit chips are packaged and then mounted on a printed circuit board (PCB). The package includes contact points to enable electrical interconnections between the integrated circuit chips and the PCB. In particular, fine wire bonds may be utilized to electrically interconnect each of the integrated circuit chips (e.g., input/output ports thereof) to the bonding points of the package, to enable functioning thereof. Wire bonds provide high flexibility in forming electrical interconnections, along with cost-effective production methods. However, the input/output ports for the wire bonds are formed on periphery regions (e.g., along a perimeter) of the integrated circuit chips, hence limiting the number and the density of the input/output ports. Furthermore, the length of the wire bonds leads to an increase in electrical resistance and energy loss, thereby increasing the power consumption and leading to excessive heat formation by the electronic device.

### SUMMARY

Aspects of the disclosure, according to some embodiments thereof, relate to semiconductor devices. More specifically, but not exclusively, aspects of the disclosure, according to some embodiments thereof, relate to methods for manufacturing forming electrically conductive lines with controlled coefficient of thermal expansion.

According to some embodiments, there is provided herein a method for forming electrically conductive lines with controlled coefficient of thermal expansion (CTE). Advantageously, in some embodiments, controlling the CTE in semiconductor devices, such as, but not limited to, integrated circuits, facilitates minimizing/preventing thermal stress between one or more electronic components or elements thereof, thereby minimizing/preventing cracking, undesired deformation (e.g., bending, twisting, and the like) of the one or more electronic components/elements, thereby enhancing the performance, the yield and the reliability of the electronic device.

Advantageously, in some embodiments, tailoring the CTE enables incorporating various materials in an electronic device (e.g., introducing various materials into an integrated circuit), and obtaining matching CTEs with various components thereof, which, in turn, enhances the performance and the yield of the electronic device.

Advantageously, in some embodiments, tailoring the CTE facilitates the thermal management of the semiconductor/electronic device. Advantageously, in some embodiments, tailing the CTE facilitates heat dissipation from semiconductor/electronic device and/or components thereof.

Advantageously, in some embodiments, the disclosed herein method enables determining the resolution of the produced conductive lines with a tailored CTE during formation thereof, allowing obtaining a line/space resolution of the conductive lines of at least about 5/5 um.

According to some embodiments, there is provided a method for forming electrically conductive lines with a controlled thermal expansion coefficient (CTE), the method comprising: applying a suspension on a surface of a substrate, the suspension comprising a solvent and a solid component, the solid component comprising a mixture of at least two types of electrically conductive nanoparticles, sintering the suspension, thereby forming the electrically conductive lines, and removing a non-sintered portion of the suspension, and wherein the at least two types of electrically conductive nanoparticles comprise: a first type of electrically conductive nanoparticles having a positive CTE, and a second type of electrically conductive nanoparticles having a different CTE than the first type of conductive nanoparticles; and wherein a ratio between the at least two types of electrically conductive nanoparticles determines a final CTE of the electrically conductive lines.

According to some embodiments, the second type of electrically conductive nanoparticles may have a negative CTE.

According to some embodiments, the CTE of the second type of electrically conductive nanoparticles may be lower by at least two orders of magnitude than the CTE of the first type of electrically conductive nanoparticles.

According to some embodiments, the CTE of the second type of electrically conductive nanoparticles may be lower by at least three orders of magnitude than the CTE of the first type of electrically conductive nanoparticles.

According to some embodiments, the method may further include drying the suspension to remove the solvent.

According to some embodiments, the sintering may include laser sintering.

According to some embodiments, the sintering may include electron beam sintering.

According to some embodiments, the first type of electrically conductive nanoparticles may include copper (Cu) nanoparticles.

According to some embodiments, the second type of electrically conductive nanoparticles may include molybdenum (Mo) nanoparticles.

According to some embodiments, the final CTE of the electrically conductive lines made of or including the first type of electrically conductive nanoparticles including copper (Cu) nanoparticles and the second type of electrically conductive nanoparticles including molybdenum (Mo) nanoparticles, may be about 7.3 ppm/° C., thereby matching a CTE of GaAs.

According to some embodiments, the second type of electrically conductive nanoparticles may include carbon nanotubes.

According to some embodiments, the final CTE of the electrically conductive lines made of or including the first type of electrically conductive nanoparticles including copper (Cu) nanoparticles and the second type of electrically conductive nanoparticles including carbon nanotubes, may be about 7.3 ppm/° C., thereby matching a CTE of GaAs.

According to some embodiments, the final CTE of the electrically conductive lines made of or including the first type of electrically conductive nanoparticles including copper (Cu) nanoparticles and the second type of electrically conductive nanoparticles including carbon nanotubes, may be about 5.5 ppm/° C., thereby matching a CTE of GaN, AlN, and SiC According to some embodiments, the final CTE of the electrically conductive lines made of or including the first type of electrically conductive nanoparticles including copper (Cu) nanoparticles and the second type of electrically conductive nanoparticles including carbon nanotubes, may be about 3.6 ppm/° C., thereby matching a CTE of Si.

According to some embodiments, the second type of electrically conductive nanoparticles may include nitinol (TiNi) nanoparticles.

According to some embodiments, the final CTE of the electrically conductive lines made of or including the first type of electrically conductive nanoparticles including copper (Cu) nanoparticles and the second type of electrically conductive nanoparticles including nitinol (TiNi) nanoparticles, may be about 7.3 ppm/° C., thereby matching a CTE of GaAs. According to some embodiments, the final CTE of the electrically conductive lines made of or including the first type of electrically conductive nanoparticles including copper (Cu) nanoparticles and the second type of electrically conductive nanoparticles including nitinol (TiNi) nanoparticles, may be about 5.5 ppm/° C., thereby matching a CTE of GaN, AlN, and SiC.

According to some embodiments, the final CTE of the electrically conductive lines made of or including the first type of electrically conductive nanoparticles including copper (Cu) nanoparticles and the second type of electrically conductive nanoparticles including nitinol (TiNi) nanoparticles, may be about 3.6 ppm/° C., thereby matching a CTE of Si.

According to some embodiments, the second type of electrically conductive nanoparticles may include tungsten (W) nanoparticles.

According to some embodiments, the final CTE of the electrically conductive lines made of or including the first type of electrically conductive nanoparticles including copper (Cu) nanoparticles and the second type of electrically conductive nanoparticles including tungsten (W) nanoparticles, may be about 5.5 ppm/° C., thereby matching a CTE of GaN, AlN, and SiC.

According to some embodiments, the final CTE of the electrically conductive lines made of or including the first type of electrically conductive nanoparticles including copper (Cu) nanoparticles and the second type of electrically conductive nanoparticles including tungsten (W) nanoparticles, may be about 3.6 ppm/° C., thereby matching a CTE of Si.

According to some embodiments, a line/space resolution of the electrically conductive lines may be at least about 5/5 um.

According to some embodiments, the method may further include removing the substrate. According to some embodiments, the substrate may be coated.

According to some embodiments, the solvent of the suspension may be selected from: water, ethanol, methanol, isopropanol, ethylene glycol, diethylene glycol monomethyl ether.

Unless otherwise defined, all technical and scientific terms used herein have the same meaning as commonly understood by one of ordinary skill in the art to which this disclosure pertains. In case of conflict, the patent specification, including definitions, governs. As used herein, the indefinite articles “a” and “an” mean “at least one” or “one or more” unless the context clearly dictates otherwise.

### BRIEF DESCRIPTION OF THE FIGURES

Some embodiments of the disclosure are described herein with reference to the accompanying figures. The description, together with the figures, makes apparent to a person having ordinary skill in the art how some embodiments may be practiced. The figures are for the purpose of illustrative description and no attempt is made to show structural details of an embodiment in more detail than is necessary for a fundamental understanding of the disclosure. For the sake of clarity, some objects depicted in the figures are not drawn to scale. Moreover, two different objects in the same figure may be drawn to different scales. In particular, the scale of some objects may be greatly exaggerated as compared to other objects in the same figure.

### In the Figures:

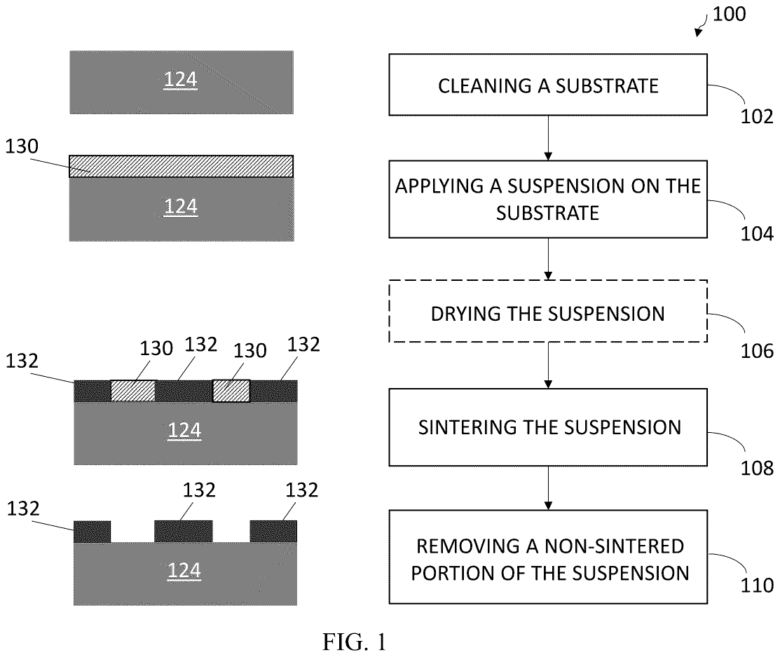

FIG. 1 schematically illustrates an example of an additive manufacturing method for forming electrically conducting lines, according to some embodiments.

### DETAILED DESCRIPTION

The principles, uses, and implementations of the teachings herein may be better understood with reference to the accompanying description and figures. Upon perusal of the description and figures present herein, one skilled in the art will be able to implement the teachings herein without undue effort or experimentation.

In the description and claims of the application, the words “include” and “have”, and forms thereof, are not limited to members in a list with which the words may be associated.

As used herein, the term “about” may be used to specify a value of a quantity or parameter (e.g. the length of an element) to within a continuous range of values in the neighborhood of (and including) a given (stated) value. According to some embodiments, “about” may specify the value of a parameter to be between 80% and 120% of the given value. For example, the statement “the length of the element is equal to about 1 m” is equivalent to the statement “the length of the element is between 0.8 m and 1.2 m”. According to some embodiments, “about” may specify the value of a parameter to be between 90 % and 110 % of the given value. According to some embodiments, “about” may specify the value of a parameter to be between 95 % and 105 % of the given value.

As used herein, according to some embodiments, the terms “substantially” and “about” may be interchangeable.

As used herein, the terms “electrically conductive lines” and “electrically conducting material regions”, “conductive regions”, “contact pads” and “conductive pattern” may, according to some embodiments, be used interchangeably. According to some embodiments, conductive lines are configured to electrically interconnect, rout and/or re-rout integrated circuit devices and/or components thereof, such as, but not limited to, microprocessors, memory devices, a chipset, a graphics device, one or more dies, and the like, or any combination thereof.

According to some embodiments, the conductive lines may refer to any electrically conductive elements, such as, but not limited to, vias, contacts, nodes, pads (e.g., contact pads, bond pads, and the like), traces, pathways, tracks, terminals, ports, and the like, or any combination thereof. Each possibility is a separate embodiment. According to some embodiments, the conductive lines may refer to and form a redistribution layer (e.g., of an integrated circuit), for example, to facilitate die stacking/assembling.

Additionally, or alternatively, in some embodiments, conductive lines may form a conducting pathway (e.g., vertical electrical connections). According to some embodiments, the conductive lines may form various types of vias, such as, but not limited to, through-vias, tented vias, blind vias, buried vias, stacked vias, and the like, or any combination thereof. Each possibility is a separate embodiment.

According to some embodiments, the conductive lines may refer to any type of metallization regions (e.g., a metallization layer on integrated circuits, and the like) configured to electrically interconnect one or more electronic components of a chip.

According to some embodiments, the conductive lines may refer to electrically conductive regions (e.g., vias) of an interposer (e.g., a coreless interposer, a 3D interposer, and the like). According to some embodiments, the conductive lines may refer to any electrically conducting portions/regions, such as conducting portions/regions (e.g., pads, vias, and the like) of an interposer, of a chip module, and the like.

According to some embodiments, the conductive lines may be configured to form ohmic contacts. According to some embodiments, the conductive lines may be configured to form rectifying (e.g., metal-semiconductor) contacts.

As used herein, according to some embodiments the term “electronic device” may refer to any device including electronic components, integrated circuits, and the like, therein, such as, but not limited to, a wearable device (e.g., a smart watch, a fitness tracker, and the like), a mobile phone (e.g., a smartphone), a tablet, a computer (e.g., a laptop), a camera, a screen (e.g., a touch screen), a television, a robot (e.g., a robotic arm, and the like), a memory device, a power storage device, a light-emitting device, and the like. According to some embodiments, the electronic device may be portable. According to some embodiments, the electronic device may refer to a non-mobile device. According to some embodiment, the electronic device may refer to a household appliance, an industrial appliance/system, a car, and the like. Each possibility is a separate embodiment. As used herein, according to some embodiments, the term “one or more electronic components” may refer to any circuit and/or electronic components/elements mounted, attached, fixed or otherwise incorporated into an electronic device. According to some embodiments, the one or more electronic components may include, among others, one or more of: a chip, a semiconductor die, a semiconductor device (e.g., a transistor), micromechanical systems (MEMS), an integrated circuit (e.g., application-specific integrated circuit), memory interfaces, input/output devices, a graphics processing unit, a microprocessor, a microcontroller, a logic chip (e.g., analog-to-digital converter), radio modem, a sensor, a signal generation circuit, a signal conversion circuit, a switch circuit, an amplifier circuit, passive components (such as, but not limited to, inductors, capacitors, and the like), and the like, or any combination thereof. Each possibility is a separate embodiment. According to some embodiments, the one or more electronic components may include, among others, one or more of: a silicon die, a silicon carbide die (e.g., a SiC metal-oxide-silicon field-effect transistor (MOSFET)), a gallium nitride die (e.g., a bare GaN high electron mobility transistor (HEMT), a gallium arsenide (GaAs) die, and the like, or any combination thereof. Each possibility is a separate embodiment.

According to some embodiments, there is provided herein a method for forming electrically conductive lines with a controlled thermal expansion coefficient (CTE), the method including: applying a suspension on a surface of a substrate, the suspension including a solvent and a solid component, the solid component including a mixture of at least two types of electrically conductive nanoparticles; drying the suspension to remove the solvent; sintering the suspension, thereby forming the electrically conductive lines; and removing a non-sintered portion of the suspension. According to some embodiments, the at least two types of electrically conductive nanoparticles include a first type of electrically conductive nanoparticles having a positive CTE, and a second type of electrically conductive nanoparticles having a different CTE than the first type of conductive nanoparticles, and wherein a ratio between the at least two electrically conductive nanoparticles determines a final CTE of the electrically conductive lines.

According to some embodiments, the disclosed method enables obtaining a matching CTE to various materials of integrated circuits, such as but not limited to, Si, GaAs, SiC, GaN, AlN. Each possibility is a separate embodiment. Advantageously, in some embodiments, matching the CTE in integrated circuits facilitates minimizing/preventing thermal stress between one or more electronic components or elements thereof in an electronic device, thereby minimizing/preventing cracking, undesired deformation (e.g., bending, twisting, and the like) of electronic components/elements of the electronic device, thereby enhancing the performance, the yield and the reliability of the electronic device.

Advantageously, in some embodiments, tailoring the CTE enables incorporating of various materials in an electronic component (e.g., integrated circuit) of an electronic device, obtaining matching CTEs with various components thereof, and, in turn, enhancing the performance and the yield of the electronic device.

Advantageously, in some embodiments, tailoring the CTE facilitates the thermal management (i.e., facilitates heat dissipation) of the electronic device.

Advantageously, in some embodiments, the disclosed herein method enables determining the resolution of the produced conductive lines with a tailored CTE during formation thereof, allowing obtaining a line/space resolution of the electrically conductive lines of at least about 5/5 um.

Reference is now made to FIG. 1, which schematically illustrates a flowchart 100 of an additive manufacturing method for forming electrically conducting lines, according to some embodiments.

According to some embodiments, the additive manufacturing method may include, among others, selective laser sintering (SLS) methods, such as but not limited to, direct SLS, direct metal laser sintering (DMLS), selective laser melting (SLM), metal lines 3D printing, electron beam melting (EBM), electron beam sintering, or any other additive manufacturing methods. Each possibility is a separate embodiment. According to some embodiments, the additive manufacturing method may include any type of directed energy deposition methods, powder-based fusion additive manufacturing methods, and the like, or any combination thereof. According to some embodiments, the additive manufacturing method may include micro-metal additive manufacturing (MMAM) methods. Each possibility is a separate embodiment.

According to some embodiments, at step 102, the method may include obtaining a substrate 124. According to some embodiments, at step 102, the additive manufacturing method may optionally include cleaning substrate 124.

According to some embodiments, cleaning substrate 124 may include performing plasma surface treatment. According to some embodiments, the plasma surface treatment may be performed by an atmospheric plasma. According to some embodiments, cleaning substrate 124 may include chemical etching (i.e., wet or dry etching) of the surface of substrate 124. According to some embodiments, cleaning substrate 124 may include dry etching of the surface of substrate 124. According to some embodiments, cleaning substrate 124 may include ultrasonic cleaning. According to some embodiments, cleaning substrate 124 may include ozone treatment of the surface of substrate 124. According to some embodiments, cleaning substrate 124 may include any combination of the abovementioned cleaning methods, or any other surface treatment/cleaning.

According to some embodiments, substrate 124 may be inert. According to some embodiments, substrate 124 may be made of or include, among others, glass (e.g., coated glass, uncoated glass, and the like), Si, ceramic material(s), polymer(s), stainless steel(s), and the like, or any combination thereof. Each possibility is a separate embodiment.

According to some embodiments, carrier substrate 124 may be rigid. As a non-limiting example, carrier substrate 124 may have a Shore hardness of about 85 D-96 D. According to some embodiments, carrier substrate 124 may be flexible. As a non-limiting example, carrier substrate 124 may have a Shore hardness in a range of about 45 D-70 D. According to some embodiments, carrier substrate 104 may be semi-rigid (e.g., of a combined hardness of the rigid and the flexible substrates). Each possibility is a separate embodiment.

According to some embodiments, substrate 124 may be a temporary substrate (i.e., removable substrate). Alternatively, in some embodiments, substrate 124 may be a non-temporary substrate.

According to some embodiments, substrate 124 may be a coated substrate. According to some embodiments, a coating of substrate 124 may be configured to facilitate adhesion of conductive lines. According to some embodiments, the coating of substrate 124 may be made of or include, among others, a seed layer of TiW and Cu. According to some embodiments, substrate 124 may be uncoated.

According to some embodiments, substrate 124 may be a substantially planar/flat substrate. According to some embodiments, substrate 124 may not be planar, e.g., substrate 124 may include a patterned surface (not shown). As a non-limiting example, the patterned surface of substrate 124 may include, among others, gaps, resulting in formatting of different surface heights, and the like.

According to some embodiments, the method may optionally include applying a coating on substrate 124 (step not shown). According to some embodiments, the coating may be applied by any suitable method, such as, but not limited to, deposition.

According to some embodiments, at step 104, the method may include applying a suspension 130 on the surface of substrate 124. According to some embodiments, suspension 130 may include a solvent and a solid component. According to some embodiments, the solid component may include a mixture of at least two types of electrically conductive nanoparticles.

According to some embodiments, the at least two types of electrically conductive nanoparticles may include 2, 3, 4, 5, 6, or more types of electrically conductive nanoparticles. Each possibility is a separate embodiment.

According to some embodiments, each of the at least two electrically conductive nanoparticles may have different particle size. According to some embodiments, a diameter of each of the at least two electrically conductive nanoparticles may be in a range of about 10-500 nm. According to some embodiments, a diameter of each of the at least two electrically conductive nanoparticles may be in a range of about 10-500 nm, about 10-100 nm, about 10-200 nm, about 10-300 nm, about 10-400 nm, about 50 -250 nm, about 100-500 nm, about 300-500 nm, and the like. Each possibility is a separate embodiment. As a non-limiting example, a first of the at least two electrically conductive nanoparticles may have a diameter of about 10-30 nm, and a second of the at least two electrically conductive nanoparticles may have a diameter of about 80-120 nm.

Alternatively, or additionally, in some embodiments, each of the at least two electrically conductive nanoparticles may have substantially the same particle size. According to some embodiments, the diameter of each of the at least two electrically conductive nanoparticles may be in a range of about 10-500 nm, about 10-100 nm, about 10-200 nm, about 10-300 nm, about 10-400 nm, about 50 -250 nm, about 100-500 nm, about 300-500 nm, and the like. Each possibility is a separate embodiment.

According to some embodiments, the at least two types of electrically conductive nanoparticles may include a first type of electrically conductive nanoparticles having a positive coefficient of thermal expansion (CTE), and a second type of electrically conductive nanoparticles having a different CTE than the first type of electrically conductive nanoparticles. In some embodiments, the different CTE of the second type of electrically conductive nanoparticles may include a different value of a positive or a negative CTE. Each possibility is a separate embodiment.

According to some embodiments, the second type of electrically conductive nanoparticles may have a negative CTE.

According to some embodiments, the CTE of the second type of electrically conductive nanoparticles may be lower by at least an order of magnitude than the CTE of the first type of electrically conductive nanoparticles. According to some embodiments, the CTE of the second type of electrically conductive nanoparticles may be lower by at least 2 orders of magnitude than the CTE of the first type of electrically conductive nanoparticles. According to some embodiments, the CTE of the second type of electrically conductive nanoparticles may be lower by at least 3 orders of magnitude than the CTE of the first type of electrically conductive nanoparticles. According to some embodiments, the CTE of the second type of electrically conductive nanoparticles may be lower by at least 4 orders of magnitude than the CTE of the first type of electrically conductive nanoparticles. According to some embodiments, the CTE of the second type of electrically conductive nanoparticles may be lower by at least 5 orders of magnitude than the CTE of the first type of electrically conductive nanoparticles. According to some embodiments, the CTE of the second type of electrically conductive nanoparticles may be lower by about 6 or more orders of magnitude than the CTE of the first type of electrically conductive nanoparticles. Each possibility is a separate embodiment.

According to some embodiments, the first type of electrically conductive nanoparticles may include, among others, copper (Cu), gold (Au), silver (Ag), nickel (Ni), titanium (Ti), tin (Sn), Molybdenum (Mo), Tungsten (W), and the like, and/or any alloys thereof, or any combination thereof. Each possibility is a separate embodiment. As a non-limiting example, the first type of electrically conductive nanoparticles may be made of or include Nitinol (NiTi) nanoparticles.

According to some embodiments, the second type of electrically conductive nanoparticles may include, among others, tungsten (W), titanium (Ti), silicon (Si), molybdenum (Mo), germanium Ge), tantalum (Ta), chromium (Cr), silver (Ag), iron (Fe), vanadium (V), zirconium (Zr), platinum (Pt), or any alloys thereof, and/or any combination thereof. Each possibility is a separate embodiment. As a non-limiting example, the second type of electrically conductive nanoparticles may be made of or include iron-cobalt-nickel alloys. Each possibility is a separate embodiment.

According to some embodiments, the second type of electrically conductive nanoparticles may include, among others, carbon-based materials, such as carbon nanotubes, carbon nanodots (e.g., carbon quantum dots), carbon nanowires, fullerenes, and the like, or any combination thereof. Each possibility is a separate embodiment. According to some embodiments, the second type of electrically conductive nanoparticles may include, among others, any type of carbon allotropy.

According to some embodiments, the first type of electrically conductive nanoparticles may include, among others, copper (Cu) nanoparticles, and the second type of electrically conductive nanoparticles may include, among others, carbon nanotubes, molybdenum (Mo) nanoparticles, nitinol (TiNi) nanoparticles, tungsten (W) nanoparticles, and the like, or any combination thereof. Each possibility is a separate embodiment.

According to some embodiments, a ratio between the at least two types of electrically conductive nanoparticles may determine a final CTE of the electrically conductive lines. According to some embodiments, the ratio between the at least two types of electrically conductive nanoparticles may include any one of: a molar ratio, an atomic ratio, a weight ratio, and the like. Each possibility is a separate embodiment. According to some embodiments, the ratio between the at least two types of electrically conductive nanoparticles may include the at least two types of electrically conductive nanoparticles may include any value in a range of about 5% to about 95% of the first type of electrically conductive nanoparticles and any value in a range of about 95% to about 5%, respectively, of the second type of electrically conductive nanoparticles. Each possibility is a separate embodiment.

According to some embodiments, the at least two types of electrically conductive nanoparticles in the suspension may include about 50% of the first type of electrically conductive nanoparticles, and about 50% of the second type of electrically conductive nanoparticles. According to some embodiments, the at least two types of electrically conductive nanoparticles in the suspension may include about 25% of the first type of electrically conductive nanoparticles, and about 75% of the second type of electrically conductive nanoparticles. According to some embodiments, the at least two types of electrically conductive nanoparticles in the suspension may include about 20% of the first type of electrically conductive nanoparticles, and about 80% of the second type of electrically conductive nanoparticles. According to some embodiments, the at least two types of electrically conductive nanoparticles in the suspension may include about 10% of the first type of electrically conductive nanoparticles, and about 90% of the second type of electrically conductive nanoparticles. According to some embodiments, the at least two types of electrically conductive nanoparticles in the suspension may include about 5% of the first type of electrically conductive nanoparticles, and about 95% of the second type of electrically conductive nanoparticles. According to some embodiments, the at least two types of electrically conductive nanoparticles in the suspension may include about 3% of the first type of electrically conductive nanoparticles, and about 97% of the second type of electrically conductive nanoparticles. According to some embodiments, the at least two types of electrically conductive nanoparticles in the suspension may include about 40% of the first type of electrically conductive nanoparticles, and about 60% of the second type of electrically conductive nanoparticles. Each possibility is a separate embodiment.

According to some embodiments, a relation between the ratio of each of the at least two types of electrically conductive nanoparticles in the suspension and the final CTE of the electrically conductive lines may not be linear.

According to some embodiments, suspension 130 may be devoid of intermetallic alloys. According to some embodiments, the solvent of suspension 130 may be made of or include, among others, water, ethanol, methanol, isopropanol, ethylene glycol, diethylene glycol monomethyl ether, and the like. Each possibility is a separate embodiment. It may be understood by one skilled in the art that different solvents produce a suspension (such as, suspension 130) with different viscosities.

According to some embodiments, applying suspension 130 on carrier 124 may be performed by, among others, an ink spay coater, a slot-die coater, an ultrasonic spin-spay coater, a spin coater, and the like, or any combination thereof. According to some embodiments, applying suspension 130 may include doctor blade coating, to facilitate formation of well-defined coating thickness.

According to some embodiments, at step 106, which is an optional step of the method, the method may include drying suspension 130 to remove the solvent therefrom. According to some embodiments, the drying may be performed, among others, by a blower, an oven, or the like.

According to some embodiments, at step 108, the method may include sintering suspension 130, thereby forming electrically conductive lines 132 according to a predefined pattern. According to some embodiments, the pattern may include electrically conducting lines having a required/predefined width, length, and distance therebetween. According to some embodiments, sintering suspension 130 may be performed, among others, by using a direct laser writer. According to some embodiments, step 108 may include 3D printing, electron beam sintering/melting, laser sintering (e.g., selective laser sintering) or any other additive manufacturing method. Each possibility is a separate embodiment.

According to some embodiments, electrically conductive lines 132 may be formed according to a predefined pattern. According to some embodiments, a line/space resolution of electrically conductive lines 132 may be at least about 5/5 um (i.e., a line width of about 5 um, a space between the lines of about 5 um). According to some embodiments, a line/space resolution of electrically conductive lines 132 may be at least about 4/4 um. According to some embodiments, a line/space resolution of electrically conductive lines 132 may be at least about 3/3 um. According to some embodiments, a line/space resolution of electrically conductive lines 132 may be at least about 2.5/2.5 um. Each possibility is a separate embodiment. According to some embodiments, since the resolution of the conductive lines is defined by the production method of the conductive lines (e.g., laser sintering, electron beam sintering, and the like), the pattern complexity may be increased while substantially maintaining the resolution thereof.

According to some embodiments, electrically conductive lines 132 may have a final CTE specifically obtained/tailored to match with a CTE of a desired electronic component (e.g., a die). According to some embodiments, composition of a solid component of suspension 130 defines the final CTE of the electrically conductive lines 132.

In particular, in some embodiments, the solid component of suspension 130 includes at least two types of electrically conductive nanoparticles. According to some embodiments, the at least two types of electrically conductive nanoparticles include a first type of electrically conductive nanoparticles having a positive CTE, and a second type of electrically conductive nanoparticles having a different CTE than the first type of electrically conductive nanoparticles. According to some embodiments, a ratio between the at least two types of electrically conductive nanoparticles determines a final CTE of the electrically conductive lines 132.

According to some embodiments, the at least two types of electrically conductive nanoparticles of the solid component of suspension 130 may include at least a first type and a second type of nanoparticles. According to some embodiments, a ratio between the first type and the second type of nanoparticles may be about 1:30, about 1:25, about 1:20, about 1:10, about 1:9, about 1:8, about 1:7, about 1:6, about 1:5, about 1:4, about 1:3, about 1:2, about 3:7, about 2:3, about 1:1, and any reciprocal ratio thereof. Each possibility is a separate embodiment.

According to some embodiments, the ratio between the at least two types of electrically conductive nanoparticles may include a weight ratio. According to some embodiments, the ratio between the at least two types of electrically conductive nanoparticles may include a molar ratio. According to some embodiments, the ratio between the at least two types of electrically conductive nanoparticles may include an atomic ratio. Each possibility is a separate embodiment.

According to some embodiments, the at least two types of electrically conductive nanoparticles may include a first type including copper (Cu) nanoparticles, and a second type including molybdenum (Mo) nanoparticles. According to some embodiments, the ratio (e.g., a weight ratio) between copper (Cu) nanoparticles and molybdenum (Mo) nanoparticles determines a final CTE of the electrically conductive lines. According to some embodiments, the ratio may include any value in a range of about 5% to about 95% of the copper (Cu) nanoparticles and any value in a range of about 95% to about 5%, respectively, of the molybdenum (Mo) nanoparticles. Each possibility is a separate embodiment. As a non-limiting example, the ratio may include about 50% of the copper (Cu) nanoparticles and about 50%, respectively, of the molybdenum (Mo) nanoparticles. As another non-limiting example, the ratio may include about 20% of the copper (Cu) nanoparticles and about 80%, respectively, of the molybdenum (Mo) nanoparticles.

According to some embodiments, a ratio in a range of about 5% to about 95% of the copper (Cu) nanoparticles and about 95% to about 5%, respectively, of the molybdenum (Mo) nanoparticles may lead to a final CTE of the electrically conductive lines of about 5.5 ppm/° C., thereby matching a CTE of GaN, AlN, and SiC.

According to some embodiments, the at least two types of electrically conductive nanoparticles may include a first type including copper (Cu) nanoparticles, and a second type including carbon nanotubes (CNTs). According to some embodiments, the ratio between the copper (Cu) nanoparticles and the CNTs determines a final CTE of the electrically conductive lines. According to some embodiments, the ratio may include any value in a range of about 5% to about 95% of the copper (Cu) nanoparticles and any value in a range of about 95% to about 5%, respectively, of the CNTs. Each possibility is a separate embodiment.

According to some embodiments, a ratio (e.g., a weight ratio, a molar ratio, an atomic ratio) of about 85%-95% of the copper (Cu) nanoparticles and about 15%-5%, respectively, of the CNTs in the solid component of suspension 130 may determine a final CTE of the electrically conductive lines of about 7.3 ppm/° C., thereby matching a CTE of GaAs. According to some embodiments, a ratio of about 90% of the copper (Cu) nanoparticles and about 10% of the CNTs in the solid component of suspension 130 may determine a final CTE of the electrically conductive lines of about 7.3 ppm/° C., thereby matching a CTE of GaAs.

According to some embodiments, a ratio (e.g., a weight ratio, a molar ratio, an atomic ratio) of about 40%-60% of copper (Cu) nanoparticles and of about 60%-40%, respectively, of the CNTs in the solid component of suspension 130 may determine a final CTE of the electrically conductive lines of about 3.6 ppm/° C., thereby matching a CTE of Si. According to some embodiments, a ratio of about 50% of copper (Cu) nanoparticles and of about 50% of the CNTs in the solid component of suspension 130 may determine a final CTE of the electrically conductive lines of about 3.6 ppm/° C., thereby matching a CTE of Si.

According to some embodiments, a ratio (e.g., a weight ratio, a molar ratio, an atomic ratio) of about 60%-80% of the copper (Cu) nanoparticles and about 40%-20%, respectively, of the CNTs in the solid component of suspension 130 may determine a final CTE of the electrically conductive lines of about 5.5 ppm/° C., thereby matching a CTE of GaN, AlN, and SiC.

According to some embodiments, the at least two types of electrically conductive nanoparticles may include a first type including copper (Cu) nanoparticles, and a second type including nitinol (TiNi) nanoparticles. According to some embodiments, the ratio between the copper (Cu) nanoparticles and the nitinol (TiNi) nanoparticles determines a final CTE of electrically conductive lines 132. According to some embodiments, the ratio may include any value in a range of about 5% to about 95% of the copper (Cu) nanoparticles and any value in a range of about 95% to about 5%, respectively, of the nitinol (TiNi) nanoparticles. Each possibility is a separate embodiment.

According to some embodiments, the at least two types of electrically conductive nanoparticles may include a first type including copper (Cu) nanoparticles, and a second type including tungsten (W) nanoparticles. According to some embodiments, the ratio between the copper (Cu) nanoparticles and the tungsten (W) nanoparticles determines a final CTE of electrically conductive lines 132. According to some embodiments, the ratio may include any value in a range of about 5% to about 95% of the copper (Cu) nanoparticles and any value in a range of about 95% to about 5%, respectively, of the tungsten (W) nanoparticles. Each possibility is a separate embodiment.

According to some embodiments, the final CTE of electrically conductive lines 132 may be about 7.3 ppm/° C., thereby matching a CTE of GaAs. According to some embodiments, the final CTE of electrically conductive lines 132 may be about 5.5 ppm/° C., thereby matching a CTE of GaN, AlN, and SiC. According to some embodiments, the final CTE of electrically conductive lines 132 may be about 3.6 ppm/° C., thereby matching a CTE of Si. Each possibility is a separate embodiment. According to some embodiments, the final CTE of electrically conductive lines 132 may be tailored to obtain substantially any required CTE to match a wafer or any other component of an integrated circuit.

According to some embodiments, at step 110, the method may include removing/washing off a non-sintered portion of suspension 130, thereby revealing/obtaining electrically conductive lines 132.

According to some embodiments, the method may be devoid of a step including subtraction of material(s). According to some embodiments, the method may be devoid of drilling, etching, and the like, or any combination thereof.

According to some embodiments, the method is a fully additive method for formation of electrically conductive lines. Alternatively, in some embodiments, the method may be implemented as a part of a semi-additive method, such as photolithography methods for integrated circuits manufacturing. Each possibility is a separate embodiment.

Although stages of methods, according to some embodiments, may be described in a specific sequence, the methods of the disclosure may include some or all of the described stages carried out in a different order. In particular, it is to be understood that the order of stages and sub-stages of any of the described methods may be reordered unless the context clearly dictates otherwise, for example, when a latter stage requires as input an output of a former stage or when a latter stage requires a product of a former stage. A method of the disclosure may include a few of the stages described or all of the stages described. No particular stage in a disclosed method is to be considered an essential stage of that method, unless explicitly specified as such.

Although the disclosure is described in conjunction with specific embodiments thereof, it is evident that numerous alternatives, modifications, and variations that are apparent to those skilled in the art may exist. Accordingly, the disclosure embraces all such alternatives, modifications, and variations that fall within the scope of the appended claims. It is to be understood that the disclosure is not necessarily limited in its application to the details of construction and the arrangement of the components and/or methods set forth herein. Other embodiments may be practiced, and an embodiment may be carried out in various ways.

The phraseology and terminology employed herein are for descriptive purpose and should not be regarded as limiting. Citation or identification of any reference in this application shall not be construed as an admission that such reference is available as prior art to the disclosure. Section headings are used herein to ease understanding of the specification and should not be construed as necessarily limiting.

1-24. (canceled)

25. A method for forming electrically conductive lines with a controlled thermal expansion coefficient (CTE), the method comprising:
applying a suspension on a surface of a substrate, the suspension comprising a solvent and a solid component, the solid component comprising a mixture of at least two types of electrically conductive nanoparticles;
sintering the suspension, thereby forming the electrically conductive lines; and
removing a non-sintered portion of the suspension;
wherein the at least two types of electrically conductive nanoparticles comprise:
a first type of electrically conductive nanoparticles having a positive CTE, and a second type of electrically conductive nanoparticles having a different CTE than the first type of conductive nanoparticles; and
wherein a ratio between the at least two types of electrically conductive nanoparticles determines a final CTE of the electrically conductive lines.

26. The method of claim 25, wherein the second type of electrically conductive nanoparticles has a negative CTE and wherein the CTE of the second type of electrically conductive nanoparticles is lower by at least three orders of magnitude than the CTE of the first type of electrically conductive nanoparticles.

27. The method of claim 25, wherein the solvent is selected from: water, ethanol, methanol, isopropanol, ethylene glycol, diethylene glycol monomethyl ether and wherein the method further comprises drying the suspension to remove the solvent.

28. The method of claim 25, wherein the sintering comprises laser sintering or electron beam sintering.

29. The method of claims 25, wherein the first type of electrically conductive nanoparticles comprises copper (Cu) nanoparticles.

30. The method of claim 25, wherein the second type of electrically conductive nanoparticles comprises molybdenum (Mo) nanoparticles.

31. The method of claim 30, wherein the final CTE of the electrically conductive lines is about 7.3 ppm/° C., thereby matching a CTE of GaAs.

32. The method of claim 25, wherein the second type of electrically conductive nanoparticles comprises carbon nanotubes.

33. The method of claim 32, wherein the final CTE of the electrically conductive lines is about 7.3 ppm/° C., thereby matching a CTE of GaAs.

34. The method of claim 32, wherein the final CTE of the electrically conductive lines is about 5.5 ppm/° C., thereby matching a CTE of GaN, AlN, and SiC.

35. The method of claim 32, wherein the final CTE of the electrically conductive lines is about 3.6 ppm/° C., thereby matching a CTE of Si.

36. The method of claim 25, wherein the second type of electrically conductive nanoparticles comprises nitinol (TiNi) nanoparticles.

37. The method of claim 36, wherein the final CTE of the electrically conductive lines is about 7.3 ppm/° C., thereby matching a CTE of GaAs.

38. The method of claim 36, wherein the final CTE of the electrically conductive lines is about 5.5 ppm/° C., thereby matching a CTE of GaN, AlN, and SiC.

39. The method of claim 36, wherein the final CTE of the electrically conductive lines is about 3.6 ppm/° C., thereby matching a CTE of Si.

40. The method of claim 25, wherein the second type of electrically conductive nanoparticles comprises tungsten (W).

41. The method of claim 40, wherein the final CTE of the electrically conductive lines is about 5.5 ppm/° C., thereby matching a CTE of GaN, AlN, and SiC.

42. The method of claim 40, wherein the final CTE of the electrically conductive lines is about 3.6 ppm/°° C., thereby matching a CTE of Si.

43. The method of claim 25, wherein a line/space resolution of the electrically conductive lines is at least about 5/5 um.

44. The method of claim 25, wherein the substrate is coated and wherein the method further comprises removing the substrate.
